(19) United States
(12) Patent Application Publication
(10) Pub. No.: US 2009/0160505 A1
(43) Pub. Date: Jun. 25, 2009

(54) POWER-UP CIRCUIT REDUCING VARIATION IN TRIGGERING VOLTAGE CAUSED BY VARIATION IN PROCESS OR TEMPERATURE IN SEMICONDUCTOR INTEGRATED CIRCUIT

(76) Inventor: Kwang Myoung RHO, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/136,350

(22) Filed: Jun. 10, 2008

(30) Foreign Application Priority Data
Dec. 20, 2007 (KR) 10-2007-0134032

(51) Int. Cl. H03K 17/22; H03K 17/14

(52) U.S. Cl. 327/143

(57) ABSTRACT

A power-up circuit that can reduce a variation of the triggering voltage that is caused by variations in process or temperature in a semiconductor integrated circuit is described. The power-up circuit includes a first detector for outputting a first triggering voltage signal according to a power voltage level and a second detector for outputting a second triggering voltage signal according to the power voltage level. The power-up circuit also includes an output unit generating and outputting a power-up signal according to the first triggering voltage signal and the second triggering voltage signal and providing the output to various internal circuits.

### CROSS-REFERENCE TO RELATED APPLICATIONS

The present application claims priority to Korean patent application number 10-2007-0134032 filed on Dec. 20, 2007, which is incorporated herein by reference in its entirety.

### BACKGROUND OF THE INVENTION

The present invention relates to a semiconductor integrated circuit, and more particularly to a power-up circuit driving an initialization of circuits mounted on a chip.

A power-up circuit as a semiconductor integrated circuit used in DRAM and ASIC products, etc. detects a potential level of an external power voltage to generate a specific initialization signal, i.e. a power-up signal, to initialize various circuits mounted on a chip.

The power-up signal has the same level as a ground voltage before the external power voltage level is stabilized and has the same level as the external power voltage when the external power voltage level is increased beyond a specific level.

In DRAM and ASIC products, the power-up signal having the above-described property is supplied to various circuits to control an initial voltage of circuit nodes requiring an initialization, i.e. nodes that should have a required designed polarity when a process for stabilizing the power voltage to a specific level is finished.

FIG. 1 shows a general power-up circuit.

Referring to FIG. 1, an inverter type detector in which a PMOS transistor P1 and a NMOS transistor N1 are serially connected detects the external power voltage VDD level, and an output node DET of the detector has different polarities according to the VDD level.

Here, the external power voltage VDD level is detected by a divider having resistors R1 and R2 serially formed between the power voltage VDD and the ground voltage VSS.

A ground voltage VSS is applied to a gate of the PMOS transistor P1, but a voltage level obtained by dividing the external voltage VDD by the resistors R1 and R2 is applied to a gate of the NMOS transistor N1.

An inverter INV1 connected to the output node DET of the detector delivers a signal PWRUP by buffering the output of the detector to other circuits in the chip.

Operational properties of the power-up circuit in FIG. 1 are as shown in a waveform diagram of FIG. 2. In FIG. 2, (A) illustrates a waveform property of the divided VDD voltage—LEVEL, (B) illustrates a waveform property of the detector output—DET, and (C) illustrates a waveform property of the final output—PWRUP.

In more detail, waveform (A) of FIG. 2 illustrates the external voltage VDD level and the resulting level obtained by dividing the external voltage VDD. In the detector of FIG. 1, a VGS value of the PMOS transistor P1 is VDD, but a VGS value of the NMOS transistor N1 becomes (R2/(R1+R2))*VDD. Therefore, where the external voltage VDD gradually increases from the ground level, the potential of the output node DET of the detector increases following the external voltage VDD through the PMOS transistor P1.

Referring to waveform (B) of FIG. 2, the output DET of the detector rises following the power voltage VDD during an initial period. In the initial period, the NMOS transistor within the inverter INV1 (not shown) is turned on earlier and thus the output PWRUP of the inverter INV1 maintains the ground level while the output DET follows the power voltage VDD. This can be further illustrated by referring to an initialization period in waveform (C) of FIG. 2. The initial period described above is referred to as an initialization period and various circuits in the chip initialize specific nodes using the PWRUP signal during this period.

Meanwhile, after the initialization is performed, the power-up signal polarity must be changed and outputted for performing a normal operation. Accordingly, properly adjusting the channel sizes of the PMOS transistor P1 and the NMOS transistor N1 of the detector is required. In other words, the transistors must be designed so that a current driving ability of the NMOS transistor N1 becomes larger than that of the PMOS transistor P1 when the external power voltage VDD becomes larger than a triggering voltage V1. According to such a design, the potential of the output node DET of the detector is lowered to the ground level when the external power voltage VDD becomes larger than the triggering voltage V1, and consequently, the power-up signal PWRUP level becomes identical to the power voltage VDD level (a normal operation period in (B) and (C) of FIG. 2).

FIG. 3 illustrates waveform properties showing the operation of the detector within the power-up circuit in view of the current driving ability of the PMOS transistor P1 and the NMOS transistor N1 according to the power voltage VDD.

In FIG. 3, (A) illustrates a waveform of a divided power voltage VDD level, (B) illustrates current waveforms of the PMOS transistor P1 and the NMOS transistor N1 within the detector, and (C) illustrates current waveforms of the PMOS transistor P1 and the NMOS transistor N1 within the detector at a NMOS transistor fast condition.

Referring to (B) of FIG. 3, the PMOS transistor P1 is first turned on and the current I(P1) increases if the power voltage VDD becomes larger than the threshold voltage VTP. At this time, the NMOS transistor N1 is in an off state. When the power voltage VDD further increases and becomes larger than ((R1+R2)/R2)*VTN, the NMOS transistor N1 is also turned on and current I(N1) starts to increase. However, at this point, there is no change in the detection level since the current I(P1) is larger than the current I(N1).

However, where the size of the NMOS transistor N1 is designed larger than the size of the PMOS transistor P1, the increase in the current I(P1) according to the power voltage VDD is larger than that of the current I(N1). Therefore, the current I(P1) and the current I(N1) become identical to each other when the power voltage VDD reaches a specific triggering voltage V1 and the polarity of the detector is changed.

As illustrated in FIG. 3, the triggering voltage V1 is the value of the external power voltage VDD corresponding to when the current I(P1) and the current I(N1) become identical to each other. This value varies according to the current properties of the NMOS N1 and PMOS P1. In other words, a large variation may occur according to a process variation or an operation temperature of a chip. This is illustrated in (C) of FIG. 3.

If the threshold voltage VTN of the NMOS transistor N1 decreases such that it's identical to the property of the PMOS transistor P1, a curve of the current I(N1) moves towards the left side and the triggering voltage V1 becomes smaller.

FIG. 4 illustrates a variation in the triggering voltage V1 according to a skew in process/temperature and a resultant restriction in the initialization/normal operation periods. In FIG. 4, (A) illustrates a waveform of the detector output—DET and (B) illustrates a waveform of the final output—PWRUP.

As shown in FIG. 4, the variation in the triggering voltage V1 of the power-up circuit according to a related art is generated according to variation in electrical properties of the PMOS transistor P1 and the NMOS transistor N1 of the detector. As a result, the initialization period or the normal operation period is encroached, or in a severe case, the power-up function is hardly performed at all. Therefore, an error in the chip operation may occur.

### SUMMARY OF THE INVENTION

A power-up circuit in a semiconductor integrated circuit that can reduce variation in a triggering voltage is described according to the present invention.

Also, there is provided a power-up circuit in a semiconductor integrated circuit that can minimize variation in a triggering voltage according to variation in process and temperature.

Further, there is provided a power-up circuit in a semiconductor integrated circuit that has a simple circuit configuration while minimizing variation in a triggering voltage according to variation in process and temperature.

Furthermore, there is provided a power-up circuit in a semiconductor integrated circuit in that variation in target areas of an initialization period and a normal operation period is minimized even when variation in process and temperature is generated.

According to a first embodiment of the present invention, there is provided a power-up circuit in a semiconductor integrated circuit, which includes: a first detector outputting a first triggering voltage signal according to a level of a power voltage; a second detector outputting a second triggering voltage signal according to the level of the power voltage; and an output unit generating and outputting a power-up signal with the first triggering voltage signal and the second triggering voltage signal.

Preferably, in respective outputs of the first detector and the second detector, directions of the triggering voltage variation according to process/temperature variation are opposite to each other.

Preferably, the power-up circuit is configured so that an output logic level of the first detector and an output logic level of the second detector are identical to each other.

Preferably, the output of the output unit is activated when one of the first triggering voltage signal and the second triggering voltage signal is inputted.

Preferably, the output unit includes a NOR gate receiving the first triggering voltage signal and the second triggering voltage signal.

According to a second embodiment of the present invention, there is provided a power-up circuit in a semiconductor integrated circuit, which includes: a divider detecting a level of a power voltage; a plurality of detectors respectively outputting corresponding triggering voltage signals according to the output signal of the divider; and an output unit receiving the plurality of the triggering voltage signals to output a power-up signal.

Preferably, the plurality of detectors include a first and second detectors, in which, in respective outputs of the first and second detectors, directions of the triggering voltage variation according to process/temperature variation are opposite to each other.

Preferably, the power-up circuit is configured so that an output logic level of the first detector and an output logic level of the second detector are identical to each other.

Preferably, the output of the output unit is activated when one of the first triggering voltage signal and the second triggering voltage signal is inputted.

Preferably, the output unit includes a NOR gate receiving the first triggering voltage signal and the second triggering voltage signal.

Preferably, the divider includes first and second resistors serially connected between the power voltage and a ground voltage.

According to a third embodiment of the present invention, there is provided a power-up circuit in a semiconductor integrated circuit, which includes: a divider detecting a level of a power voltage; a first detector outputting a first triggering voltage signal according to the output signal of the divider; a second detector outputting a second triggering voltage signal according to the output signal of the divider; and an output unit generating and outputting a power-up signal with the first triggering voltage signal and the second triggering voltage signal.

Preferably, in respective outputs of the first detector and the second detector, directions of the triggering voltage variation according to process/temperature variation are opposite to each other.

Preferably, the power-up circuit is configured so that an output logic level of the first detector and an output logic level of the second detector are identical to each other.

Preferably, the output of the output unit is activated when one of the first triggering voltage signal and the second triggering voltage signal is inputted.

Preferably, the output unit includes a NOR gate receiving the first triggering voltage signal and the second triggering voltage signal.

Preferably, the divider includes first and second resistors serially connected between the power voltage and a ground voltage.

According to a fourth embodiment of the present invention, there is provided a power-up circuit in a semiconductor integrated circuit, which includes: a first divider detecting a level of a power voltage; a second divider detecting the level of the power voltage; a first detector outputting a first triggering voltage signal according to the output signal of the first divider; and a second detector outputting a second triggering voltage signal according to the output signal of the second divider.

Preferably, in respective outputs of the first detector and the second detector, directions of the triggering voltage variation according to process/temperature variation are opposite to each other.

Preferably, the power-up circuit is configured so that an output logic level of the first detector and an output logic level of the second detector are identical to each other.

Preferably, the power-up circuit further includes an output unit generating and outputting a power-up signal with the first triggering voltage signal and the second triggering voltage signal.

Preferably, the output of the output unit is activated when one of the first triggering voltage signal and the second triggering voltage signal is inputted.

Preferably, the output unit includes a NOR gate receiving the first triggering voltage signal and the second triggering voltage signal.

Preferably, the first divider includes first and second resistors serially connected between the power voltage and a ground voltage.

Preferably, the second divider includes first and second resistors serially connected between the power voltage and a ground voltage.

According to a fifth embodiment of the present invention, there is provided a power-up circuit in a semiconductor integrated circuit, which includes: a plurality of dividers respectively detecting a level of a power voltage; a plurality of detectors correspondingly connected to the respective dividers and respectively outputting triggering voltage signals in response to the output signal of the corresponding divider; and an output unit receiving the output signals of the respective detectors to output a power-up signal.

Preferably, the plurality of detectors includes first and second detectors, wherein in respective outputs of the first and second detectors, directions of the triggering voltage variation according to process/temperature variation are opposite to each other.

Preferably, the power-up circuit is configured so that an output logic level of the first detector and an output logic level of the second detector are identical to each other.

Preferably, the output of the output unit is activated when one of the first triggering voltage signal and the second triggering voltage signal is inputted.

Preferably, the output unit includes a NOR gate receiving the first triggering voltage signal and the second triggering voltage signal.

Preferably, each of the plurality of the divider includes first and second resistors serially connected between the power voltage and a ground voltage.

The present invention aids in performing a stable initialization of a chip in a power-up circuit having small variation in a triggering voltage according to a process/temperature variation. Also, the present invention has an advantage that can realize a power-up circuit having a simple circuit configuration while performing a stable power-up, and thus can be valuably utilized in DRAM and ASIC products with high speed and high integration

### BRIEF DESCRIPTION OF THE DRAWINGS

FIG. 1 is a circuit diagram showing a conventional power-up circuit.

FIG. 2 is a waveform diagram illustrating an operation of FIG. 1.

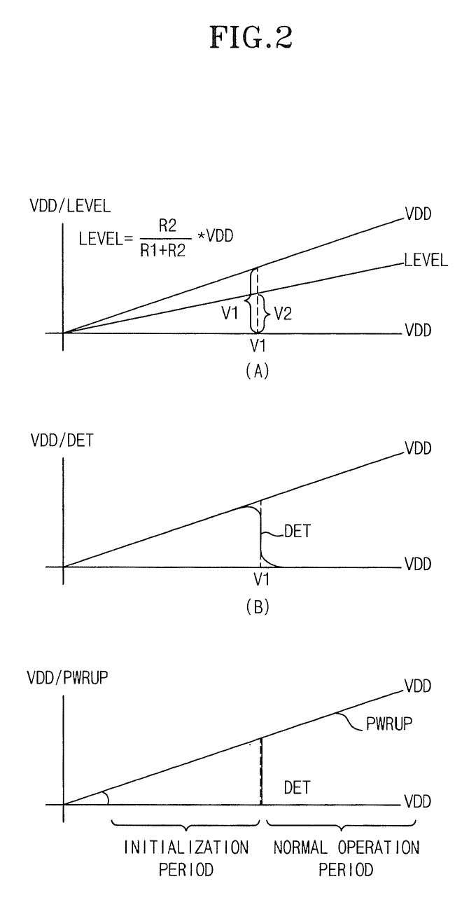

FIG. 3 is a waveform diagram illustrating an output curve of the DET of a detector in FIG. 1.

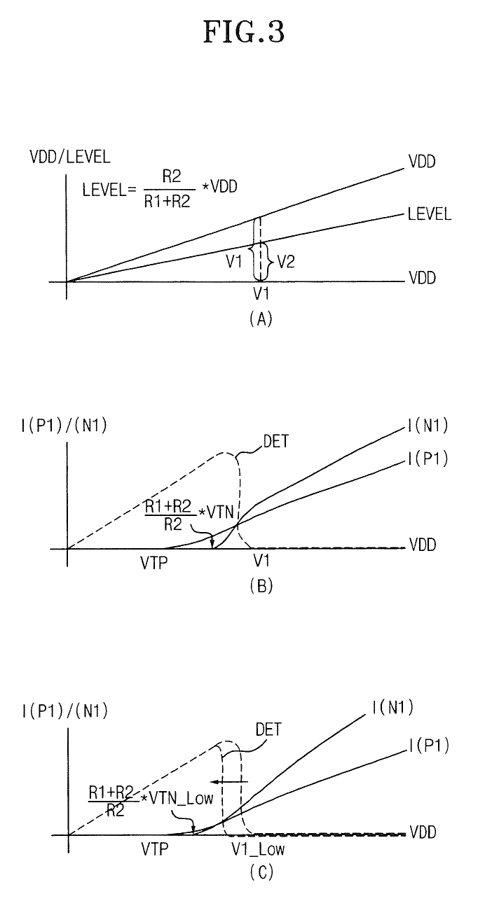

FIG. 4 is a waveform diagram illustrating the process/temperature skewing of a triggering level of FIG. 1.

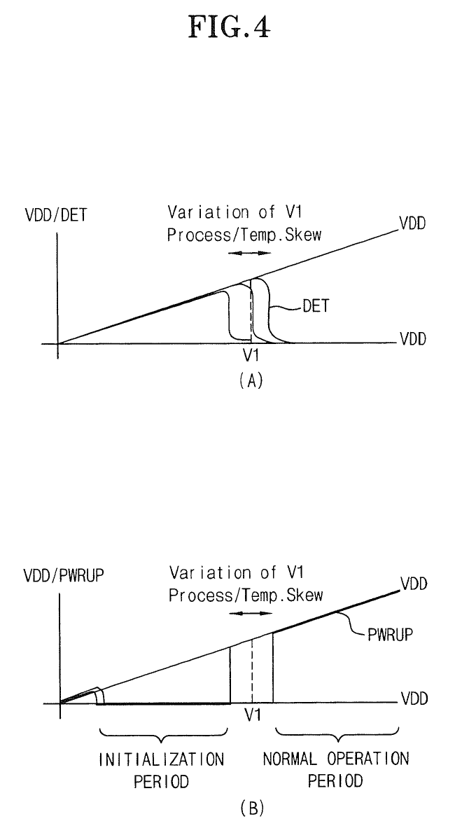

FIG. 5 is a circuit diagram showing a power-up circuit according to a first embodiment of the present invention.

FIG. 6 is a waveform diagram illustrating a reduction in the process/temperature skewing according to the configuration in FIG. 5.

FIG. 7 is a waveform diagram illustrating a skew property of a final output—PWRUP according to the configuration in FIG. 5 as compared with the conventional configuration.

FIG. 8 is a circuit diagram showing a power-up circuit according to a second embodiment of the present invention.

### DESCRIPTION OF SPECIFIC EMBODIMENTS

Hereinafter, preferred embodiments of the present invention will be described in detail with reference to the accompanying drawings.

A power-up circuit according to the present invention including two detectors having opposite triggering voltage V1 variation properties in response to the same process/temperature variation and a power-up signal generated using the respective outputs of these detectors in order to reduce a variation in a triggering voltage V1 of a detector according to the process/temperature variation. In this case, only the first triggered detector of the two detectors influences the power-up signal. Thus, the entire variation of the triggering voltage V1 can be reduced by half.

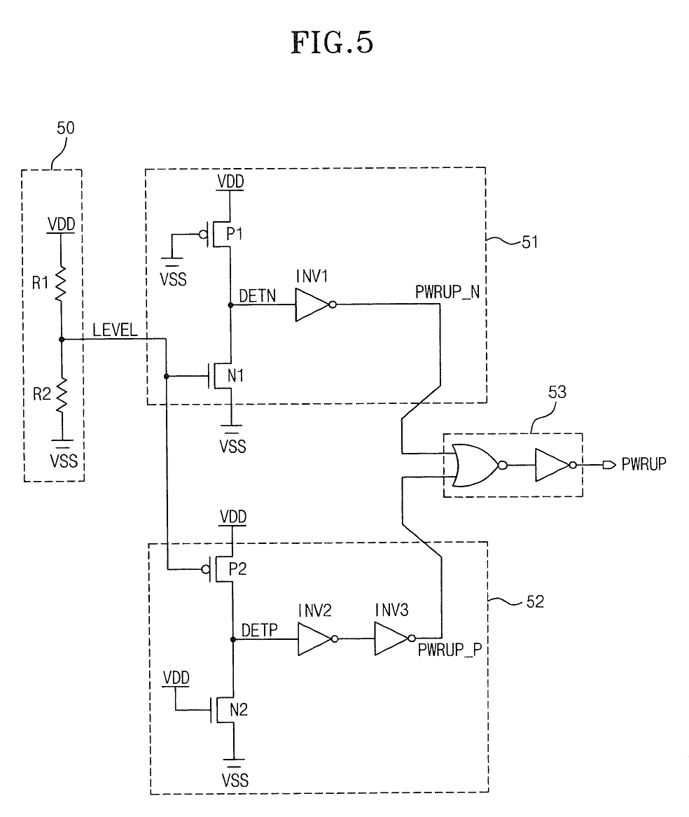

FIG. 5 shows a power-up circuit according to a first embodiment of the present invention having two detectors 51 and 52 in which variations in the triggering voltage are opposite each other according to a process/temperature variation.

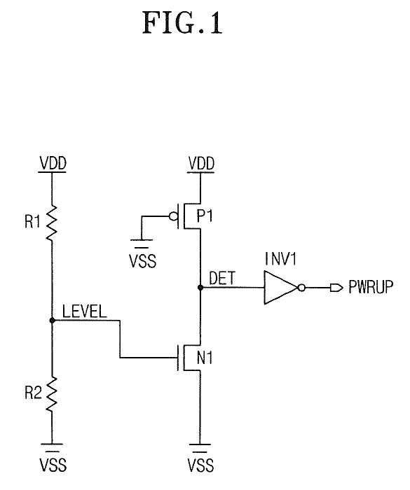

In FIG. 5, the detector 51 is configured in the same manner as the circuit shown in FIG. 1. The detector 52 is structured such that the power voltage VDD level divided by resistors R1/R2 is supplied to a gate of a PMOS transistor P2 and the power voltage VDD, not divided, is supplied to a gate of a NMOS transistor N2. Therefore, an output DET_P of the detector 52 is maintained at the ground voltage level by the NMOS transistor N2 in the initialization period and follows the power voltage VDD as a current driving ability of the PMOS transistor P2 exceeds a current driving ability of the NMOS transistor N2 after a specific triggering voltage V1.

In the above-described configuration as shown in FIG. 5, it is preferable that respective outputs of the detector 51 and detector 52 have opposite triggering voltage variation directions according to the process/temperature variation.

An output logic level of the detector 51 and an output logic level of the detector 52 may also become identical to each other by adjusting the number of inverters. Specifically, the detector 51 in FIG. 5 has a single inverter INV1 and the detector 52 has inverters INV2 and INV3. The number of inverters may be adjustable making it possible under such a condition that the output logic levels of the detector 51 and the detector 52 become identical to each other.

In FIG. 5, the triggering voltage variation directions of the output signals DET_NDET_N and DET_P of the respective detectors 51 and 52 are opposite to each other as the NMOS transistor and the PMOS transistor are reversed in the detector 51 and the detector 52. In other words, where the current driving ability of the NMOS transistor is increased and the current driving ability of the PMOS transistor is decreased by the process variation (NMOS fast & PMOS slow process condition), the triggering voltage of the output signal DET_NDET_N is reduced while the triggering voltage of the output signal DET_P is increased compared with a conventional process condition. In a NMOS slow & PMOS fast process condition, the triggering voltage of the output signal DET_NDET_N is increased while the triggering voltage of the output signal DET_P is reduced compared with a conventional process condition.

Herein, reference numeral 50 denotes the resistor divider and reference numeral 53 denotes an output unit. The divider 50 divides the power voltage VDD via the resistor R1 and R2. The output unit 53 includes a NOR gate NOR-combining the outputs of the detectors 51 and 52 PWRUP_N, PWRUP_P and an inverter inverting the output of the NOR gate and outputting it as an output signal PWRUP.

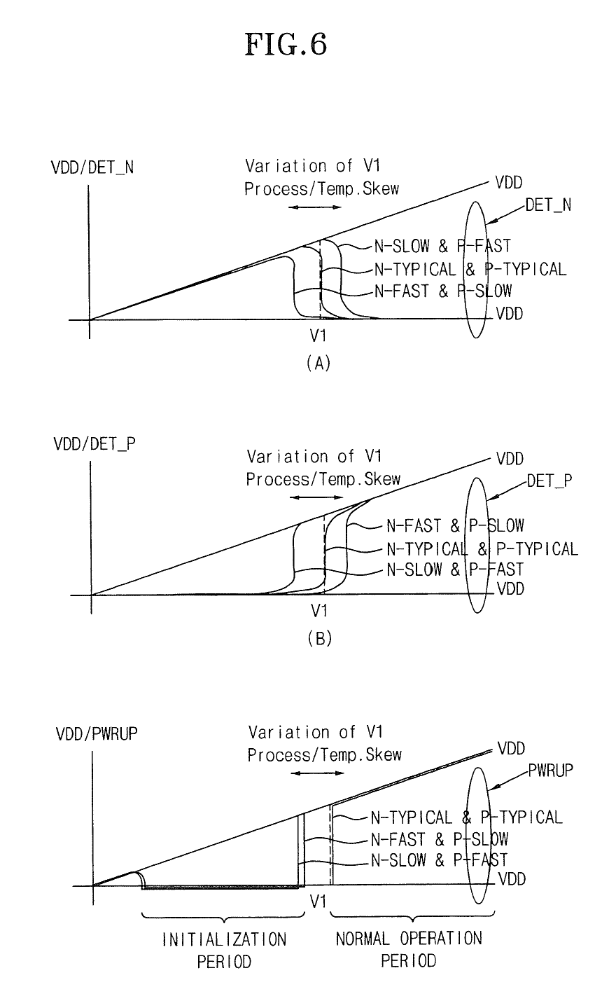

FIG. 6 is a waveform diagram illustrating a reduction in the process/temperature skew according to the power-up circuit configuration in FIG. 5. In FIG. 6, (A) illustrates an output property of the detector 51—DET_NDET_N, (B) illustrates an output property of the detector 52—DET_P, and (C) illustrates a skew property of the final output—PWRUP.

The initialization signal that is supplied to various circuits within the chip is generated in the output unit 53 by logically NOR-combining operating signals PWRUP_N and PWRUP_P that correspond to the polarities of the respective detectors. Therefore, the power-up signal PWRUP is influenced by the signal PWRUP_N or PWRUP_P that is triggered first.

In a conventional process, where the channel size within the detector is adjusted such that the triggering voltage levels of the two detectors 51 and 52 are identical, DET_N and PWRUP_N are triggered first in a NMOS fast & PMOS slow process, and DET_P and PWRUP_P are triggered first in the opposite process condition, i.e. NMOS slow & PMOS fast process condition (waveform (A) and (B) of FIG. 6).

However, as can be appreciated from waveform (C) of FIG. 6, the final PWRUP signal obtained by NOR-combing operating signals PWRUP_N and PWRUP_P does not vary largely even in the two extreme process conditions.

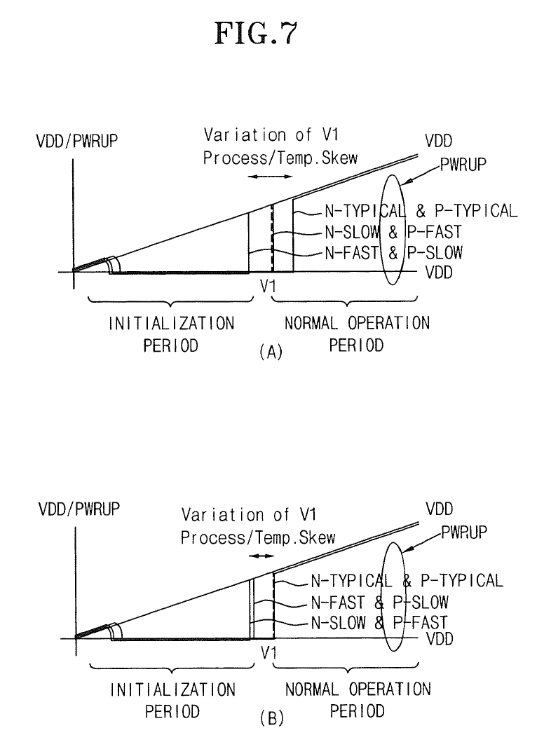

FIG. 7 illustrates a comparison of waveform properties between the conventional power-up circuit and the power-up circuit according to the present invention. In FIG. 7, (A) illustrate a skew property of PWRUP in the conventional circuit according to the configuration of FIG. 1, and (B) illustrate a skew property of PWRUP in the circuit of present invention according to the configuration of FIG. 5.

As shown, the conventional power-up circuit shows a large variation in triggering voltage in the NMOS fast & PMOS slow condition and the NMOS slow & PMOS fast condition, while the variation in triggering voltage is much smaller in the same two extreme conditions according to the power-up circuit of the present invention. Therefore, the triggering voltage variation according to a variation in process/temperature in the novel power-up circuit according to the present invention may be reduced to almost half of that of the conventional circuit ((A) and (B) of FIG. 7).

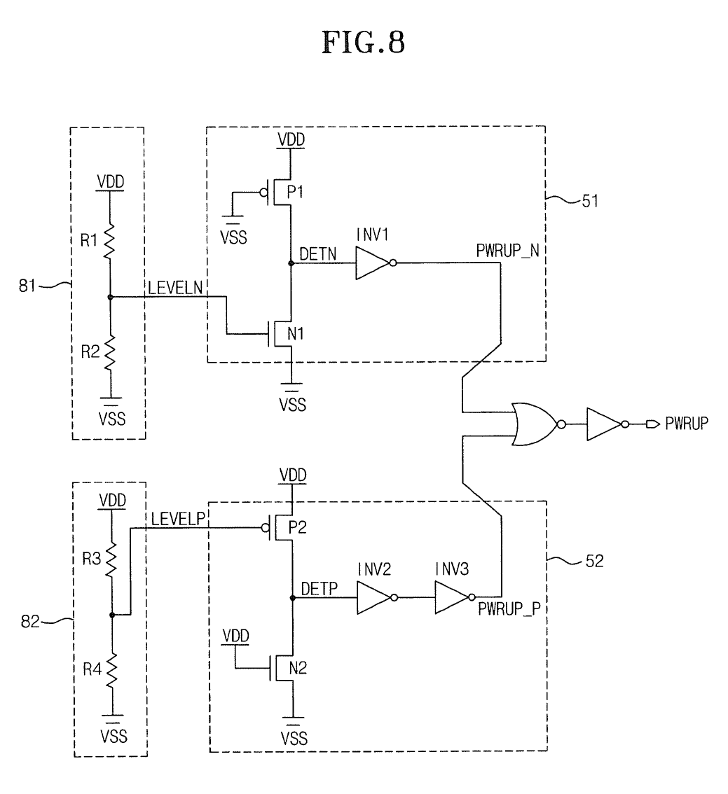

FIG. 8 shows a second embodiment of the present invention, in which the resistor dividers 81, 82 are separated for dividing the power voltage for the respective detectors 51 and 52. If the resistor divider is separated with respect to the detectors, there is an advantage in that the triggering properties of the respective detectors can be adjusted independently of each other.

Those skilled in the art will appreciate that the specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

What is claimed is:

1. A power-up circuit in a semiconductor integrated circuit, comprising:
a first detector outputting a first triggering voltage signal according to a power voltage level;
a second detector outputting a second triggering voltage signal according to the power voltage level; and
an output unit generating and outputting a power-up signal according to the first triggering voltage signal and the second triggering voltage signal.

2. The power-up circuit in a semiconductor integrated circuit as set forth in claim 1, wherein in respective outputs of the first detector and the second detector have triggering voltage variation directions opposite to each other according to a process/temperature variation.

3. The power-up circuit in a semiconductor integrated circuit as set forth in claim 2, wherein the power-up circuit is configured so that an output logic level of the first detector and an output logic level of the second detector are identical to each other.

4. The power-up circuit in a semiconductor integrated circuit as set forth in claim 1, wherein the output of the output unit is activated when one of the first triggering voltage signal and the second triggering voltage signal is inputted.

5. The power-up circuit in a semiconductor integrated circuit as set forth in claim 4, wherein the output unit includes a NOR gate receiving the first triggering voltage signal and the second triggering voltage signal.

6. A power-up circuit in a semiconductor integrated circuit, comprising:
a divider detecting a power voltage level;
a plurality of detectors respectively outputting corresponding triggering voltage signals according to an output signal of the divider; and
an output unit receiving the plurality of the triggering voltage signals to output a power-up signal.

7. The power-up circuit in a semiconductor integrated circuit as set forth in claim 6, wherein the plurality of detectors includes first and second detectors, and
wherein respective outputs of the first and second detectors have triggering voltage variation directions opposite to each other according to a process/temperature variation.

8. The power-up circuit in a semiconductor integrated circuit as set forth in claim 7, wherein the power-up circuit is configured so that output logic levels of the first detectors and output logic levels of the second detectors are identical to each other.

9. The power-up circuit in a semiconductor integrated circuit as set forth in claim 6, wherein the output of the output unit is activated when one of first triggering voltage signals and second triggering voltage signals is inputted.

10. The power-up circuit in a semiconductor integrated circuit as set forth in claim 9, wherein the output unit includes a NOR gate receiving the first triggering voltage signals and the second triggering voltage signals.

11. The power-up circuit in a semiconductor integrated circuit as set forth in claim 6, wherein the divider includes first and second resistors serially connected between the power voltage and a ground voltage.

12. A power-up circuit in a semiconductor integrated circuit, comprising:
a divider detecting a power voltage level;
a first detector outputting a first triggering voltage signal according to an output signal of the divider;
a second detector outputting a second triggering voltage signal according to the output signal of the divider; and
an output unit generating and outputting a power-up signal according to the first triggering voltage signal and the second triggering voltage signal.

13. The power-up circuit in a semiconductor integrated circuit as set forth in claim 12, wherein in respective outputs of the first detector and the second detector have triggering voltage variation directions opposite to each other according to a process/temperature variation.

14. The power-up circuit in a semiconductor integrated circuit as set forth in claim 13, wherein the power-up circuit is configured so that an output logic level of the first detector and an output logic level of the second detector are identical to each other.

15. The power-up circuit in a semiconductor integrated circuit as set forth in claim 12, wherein the output of the output unit is activated when one of the first triggering voltage signal and the second triggering voltage signal is inputted.

16. The power-up circuit in a semiconductor integrated circuit as set forth in claim 15, wherein the output unit includes a NOR gate receiving the first triggering voltage signal and the second triggering voltage signal.

17. The power-up circuit in a semiconductor integrated circuit as set forth in claim 12, wherein the divider includes first and second resistors serially connected between the power voltage and a ground voltage.

18. A power-up circuit in a semiconductor integrated circuit, comprising:
a first divider detecting a power voltage level;
a second divider detecting the power voltage level;
a first detector outputting a first triggering voltage signal according to an output signal of the first divider; and
a second detector outputting a second triggering voltage signal according to an output signal of the second divider.

19. The power-up circuit in a semiconductor integrated circuit as set forth in claim 18, wherein in respective outputs of the first detector and the second detector have triggering voltage variation directions opposite to each other according to a process/temperature variation.

20. The power-up circuit in a semiconductor integrated circuit as set forth in claim 19, wherein the power-up circuit is configured so that an output logic level of the first detector and an output logic level of the second detector are identical to each other.

21. The power-up circuit in a semiconductor integrated circuit as set forth in claim 18, further comprising an output unit generating and outputting a power-up signal according to the first triggering voltage signal and the second triggering voltage signal.

22. The power-up circuit in a semiconductor integrated circuit as set forth in claim 21, wherein the output of the output unit is activated when one of the first triggering voltage signal and the second triggering voltage signal is inputted.

23. The power-up circuit in a semiconductor integrated circuit as set forth in claim 22, wherein the output unit includes a NOR gate receiving the first triggering voltage signal and the second triggering voltage signal.

24. The power-up circuit in a semiconductor integrated circuit as set forth in claim 18, wherein the first divider includes first and second resistors serially connected between the power voltage and a ground voltage.

25. The power-up circuit in a semiconductor integrated circuit as set forth in claim 18, wherein the second divider includes first and second resistors serially connected between the power voltage and a ground voltage.

26. A power-up circuit in a semiconductor integrated circuit, comprising:
a plurality of dividers respectively detecting a power voltage level;
a plurality of detectors correspondingly connected to the respective plurality of dividers and respectively outputting triggering voltage signals in response to an output signal of the corresponding divider; and
an output unit receiving output signals of the respective detectors to output a power-up signal.

27. The power-up circuit in a semiconductor integrated circuit as set forth in claim 26, wherein the plurality of detectors includes first and second detectors, and
wherein respective outputs of the first and second detectors have triggering voltage variation directions opposite to each other according to a process/temperature variation.

28. The power-up circuit in a semiconductor integrated circuit as set forth in claim 27, wherein the power-up circuit is configured so that output logic levels of the first detectors and output logic levels of the second detectors are identical to each other.

29. The power-up circuit in a semiconductor integrated circuit as set forth in claim 26, wherein the output of the output unit is activated when one of first triggering voltage signals and second triggering voltage signals is inputted.

30. The power-up circuit in a semiconductor integrated circuit as set forth in claim 29, wherein the output unit includes a NOR gate receiving the first triggering voltage signals and the second triggering voltage signals.

31. The power-up circuit in a semiconductor integrated circuit as set forth in claim 26, wherein each divider of the plurality of the dividers includes first and second resistors serially connected between the power voltage and a ground voltage.
